(19) United States
(12) Patent Application Publication
(10) Pub. No.: US 2015/0004366 A1
(43) Pub. Date: Jan. 1, 2015

(54) SUBSTRATE WITH HIGH FRACTURE STRENGTH

(71) Applicant: National Tsing Hua University, Hsinchu (TW)

(72) Inventor: Jer-Liang Yeh, Taichung City (TW)

(21) Appl. No.: 14/489,975

(22) Filed: Sep. 18, 2014

Related U.S. Application Data
(63) Continuation-in-part of application No. 12/534,203, filed on Aug. 3, 2009.

(51) Int. Cl. H01L 31/028; H01L 29/04; H01L 29/06

(52) U.S. Cl. CPC H01L 31/028; H01L 29/0669; H01L 29/04
USPC 428/141

(57) ABSTRACT

The invention discloses a substrate with high fracture strength. The substrate according to the present invention includes a plurality of nanostructures. The substrate has a first surface, where the nanostructures protrude from the first surface. Through the formation of the nanostructures, the fracture strength of the substrate is enhanced.

### PRIORITY CLAIM

This application claims the benefit of the filing date of U.S. patent application Ser. No. 12/534,203, filed Aug. 3, 2009, entitled “SUBSTRATE WITH HIGH FRACTURE STRENGTH,” and the contents of which are hereby incorporated by reference in their entirety.

### FIELD OF THE INVENTION

The invention relates to a substrate, more particularly, to a substrate with high fracture strength.

### BACKGROUND

With the ongoing development of semiconductor processing technologies, and increasing number of semiconducting components have been researched and produced. In general, semiconducting components are implemented by forming several layer structures on a substrate. Therefore, the substrate has become the most basic and fundamental part of a component.

For example, the solar cell in the prior art usually utilizes a semiconductor wafer (e.g. Si wafer) as the substrate. However, the Si wafer is usually made of a brittle material, which is easily fractured by outside impact, especially the outside impact it would incur in the assembling process of the solar cell. Besides solar cells, Si wafers are generally utilized in various other semiconductor products. With the increasing demand of semiconductor components, the supplement of the Si wafer is tightened. Therefore, preventing the Si wafer material from being wasted (e.g. fractured by an outer impact) becomes an urgent problem and also figuring out how to raise the yield of the process. In the example of the solar cell, if it is formed on a substrate with high fracture strength, the possibility of the substrate breaking in the assembling process can be eliminated.

Please refer to FIG. 1A and FIG. 1B. FIG. 1A and FIG. 1B are pictures shot in the fracture strength test on a test piece Si wafer in the prior art. The test piece Si wafer is made of monocrystalline silicon. During the stressing period, the stress may be concentrated on particular areas of the test piece, where some cracks will then appear. When the stress increases, the crack propagation becomes more obvious, until the test piece finally breaking into several pieces, as shown in FIG. 1B.

The test piece Si wafer in the prior art will have the stress concentrated to particular areas of the test piece. If the stress can be spread evenly throughout the whole Si test piece during the test, the fracture toughness may be increased.

Therefore, the invention discloses a substrate with high fracture toughness in order to solve the aforementioned problems.

### SUMMARY OF THE INVENTION

An objective of the present invention is to provide a substrate with high fracture toughness.

According to an embodiment, the substrate has a plurality of first nanostructures. The substrate has a first surface. The first nanostructures protrude from the first surface of the substrate. In other words, the substrate has the first nanostructures formed on its first surface. By forming the first nanostructures, the fracture strength of the substrate is enhanced.

The advantages and spirit of the invention may be understood by the following recitations together with the appended drawings.

### BRIEF DESCRIPTION OF THE DRAWINGS

FIGS. 1A and 1B are pictures shot of the fracture strength test on a Si wafer test piece of the prior art.

FIGS. 2A, 2B and 2C are intersectional views illustrating a substrate according to embodiments of the invention.

FIGS. 3A and 3B are outside views illustrating the first nanostructures of the substrate according to the invention respectively.

FIG. 4 is an example illustrating a distribution formation of the first nanostructures according to an embodiment of the present invention.

FIG. 5 is a sectional view illustrating the substrate according to another embodiment of the invention.

FIGS. 6A and 6B are testing data from the fracture strength test of the substrate according to the present invention.

FIGS. 6C and 6D are pictures shot of the fracture strength test of the substrate according to the present invention.

FIGS. 7A and 7B are testing data of the bending strength test of the substrate according to the present invention.

FIG. 8 is testing data of the relationship of the stress concentration factor and aspect ratio according to the present invention.

FIG. 9 is a schematic view of the substrate according to an embodiment of the present invention.

FIGS. 10A, 10B, 10C, 10D, 10E and 1OF are schematic views of relationship of pitch width and depth of nanostructures respectively.

FIGS. 11A and 11B respectively depict a schematic figure of relationship of nanostructure depth and bending strength of the IC class wafer and solar class wafer.

### DETAILED DESCRIPTION

The scope of the present invention is to provide a substrate with high fracture toughness. The substrate can be used to produce any kind of semiconductor components, for example logic IC, light emitting diodes (LED), solar cells, etc.

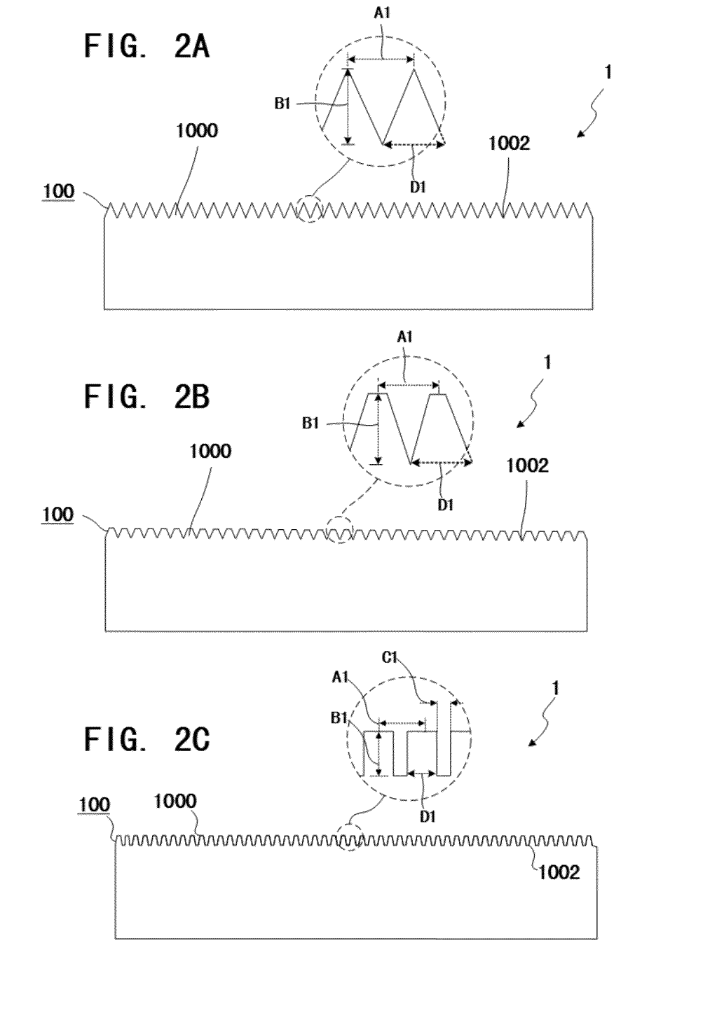

Please refer to FIG. 2A to FIG. 2C. FIG. 2A and FIG. 2C are intersectional views illustrating a substrate 1 according to some embodiments of the present invention. In practical application, the substrate 1 of the present invention can be a monocrystalline substrate or a polycrystalline substrate.

In practical application, the substrate can be made of, but is not limited to, a material composed of glass, silicon, germanium, carbon, aluminum, GaN, GaAs, GaP, AlN, sapphire, spinel, Al₂O₃, SiC, ZnO, MgO, LiAlO₂, LiGaO₂ or MgAl₂O₄.

As shown in FIG. 2A to FIG. 2C, the substrate 1 has a plurality of first nanostructures 1000. The first nanostructures 1000 can be of a tip shaped structure with a decreasing diameter as shown in FIG. 2A or a nanorod (nanopiller) as shown in FIG. 2B or FIG. 2C. The substrate 1 has a first surface 100. In the present embodiment of the present invention, the first nanostructures 1000 are protruded from the first surface 100 of the substrate 1 and are rod shaped or pyramid shaped. In other words, in the present embodiment, the substrate 1 has the first nanostructures 1000 formed on its first surface 100 through an etching process. Therefore, the substrate 1 and the nanostructures 1000 are made of the same material and formed on the same piece. In an embodiment of the present invention, if the substrate 1 is a monocrystalline substrate, the first surface 100 of the monocrystalline substrate may have a crystal orientation, which can be [100] or [111].

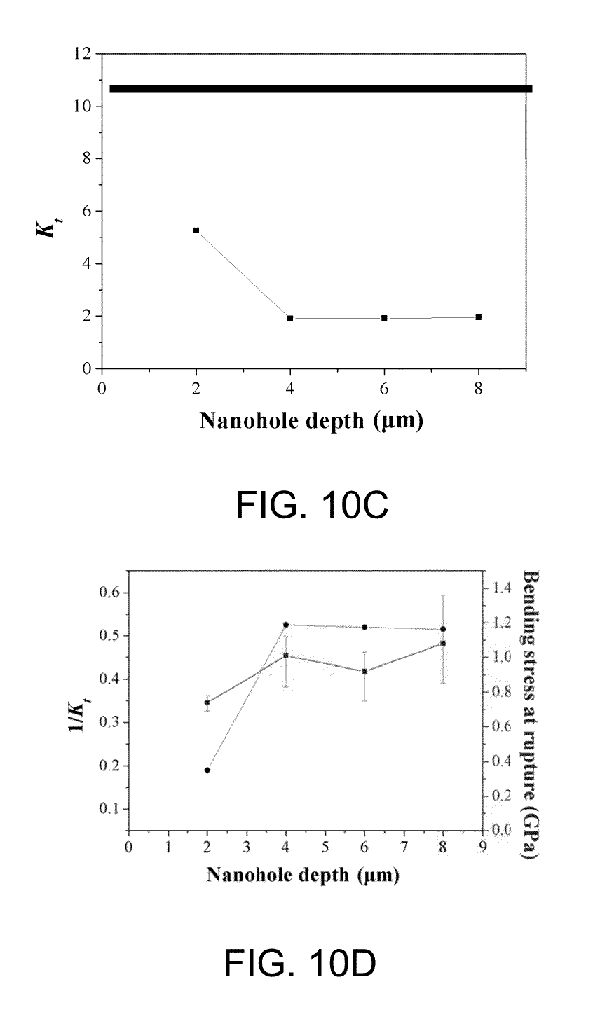

By forming the first nanostructures 1000 of the surface of the substrate 1, the fracture strength thereof is enhanced. Additionally, it should be noted that the first nanostructures 1000 may also be referred to as a hole or a concave formed on the surface of the substrate 1 in some cases. Moreover, while the nanostructure is of a tip, rod, pyramid or any other shaped material being, the nanostructure itself may either be transparent or non-transparent. In addition, the substrate 1 may have at least one working zone Z2 and at least one reserved zone Z1. The working zone Z2 is covered by an epitaxial layer and is usually disposed on the center of the substrate in order to be a chip and the reserved zone Z1 allows the nanostructures to be formed thereon so as to reinforce the substrate 1 while the reserved zone Z1 may be exposed to the atmosphere directly without being treated by a doping process or having no epitaxial layer formed thereon. Furthermore, the reserved zone Z1 is usually formed on the edge or fringe of the substrate as illustrated in FIG. 9.

Moreover, the working zone Z2 may have a plurality of logic chips or photoelectric transformation chips to be diced and formed thereon, where the said chips are ready for the packaging process after it has been diced by a dicing process respectively.

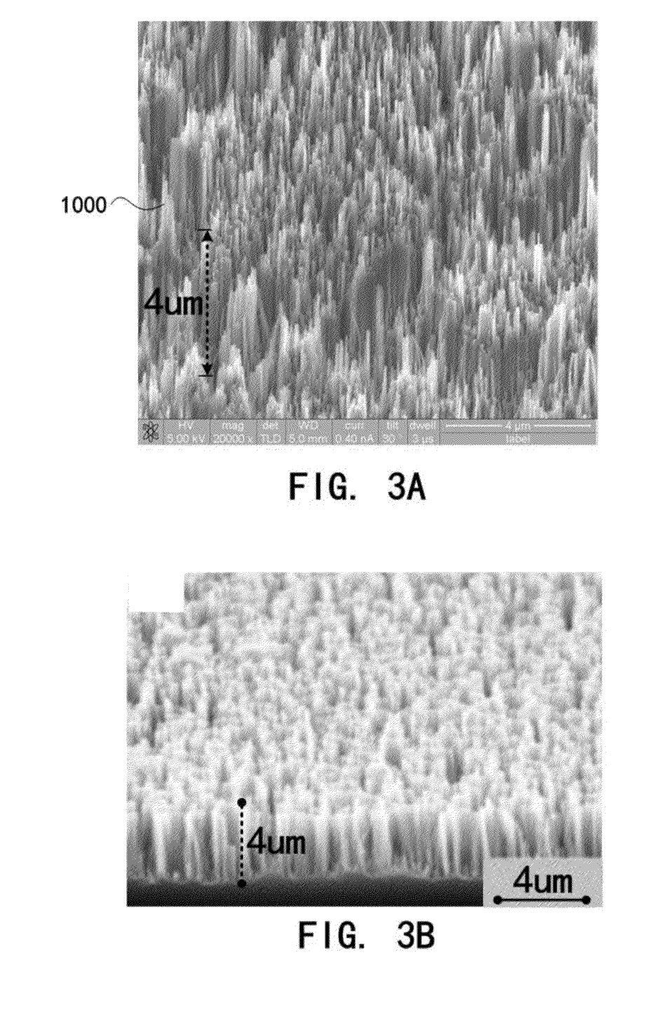

Note that FIG. 2A, FIG. 2B and FIG. 2C are schematic diagrams that demonstrate the shapes of the first nanostructures 1000 in the present invention. In practical applications, the first nanostructures 1000 preferably are shaped like individual or adjacent protruding rods. In an embodiment of the present invention, the gap width between two adjacent tops of the first nanostructures 1000 can be in the range of several dozens of nanometers to several hundreds of nanometers, where the height of each first nanostructure 1000 can be in the μm scale. In an embodiment of the present invention, the first nanostructures 1000 are formed compactly and evenly on the first surface of the substrate. In this embodiment of the present invention, each of the nanostructures 1000 is a protruding rod protruding from the substrate (shown in FIG. 3A and FIG. 3B) and is formed evenly on the first surface of the substrate.

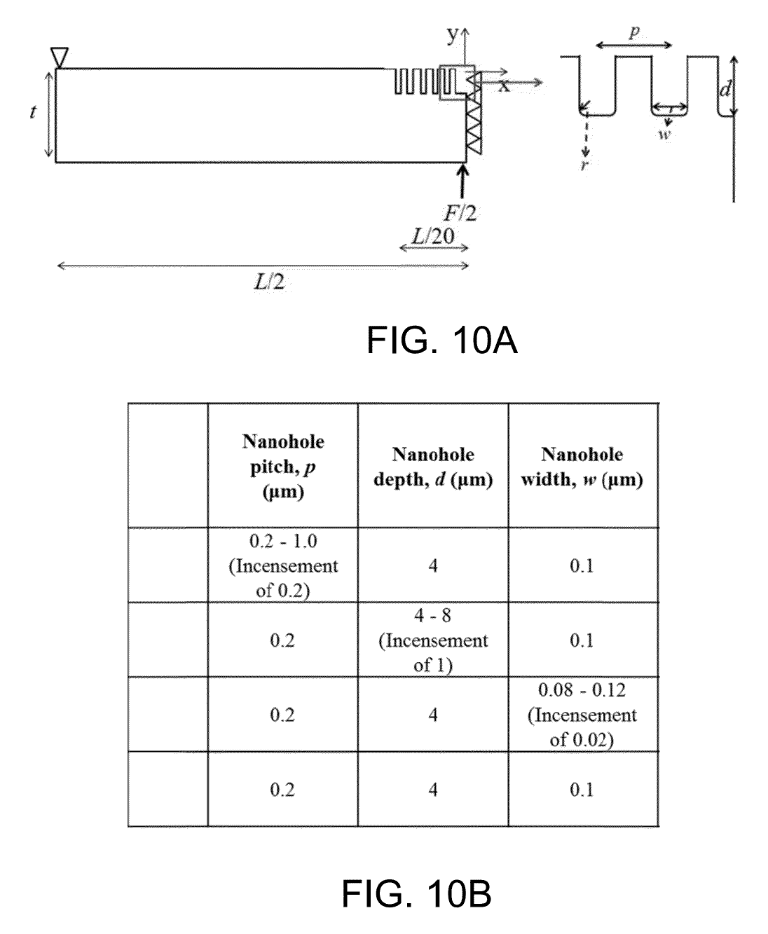

The dimension of the nanostructure is herein described. More specifically, the dimension of the nanostructure can be defined by an aspect ratio thereof. Please refer to FIG. 2A to FIG. 2C, through the figures, the formula of the first aspect ratio is R1=B1/D1, wherein D1 is an average width of the first nanostructures 1000, and B1 is a height (or depth) of each first nanostructure 1000. Furthermore, it should be known that the aspect ratio of the nanostructure is suggested to be higher than 1.5 in order to have better results, more specifically, please refer to FIG. 8. It is clearly shown that while the aspect ratio is lower than 1.5, the stress concentration factor (SCF) increases rapidly. Since the SCF is inversely proportional to the ability to bend brittle materials, the fracture strength can be improved significantly by forming a nanostructure with an aspect ratio larger than 1.5.

More specifically, in the present embodiment of the present invention, each of the first nanostructures 1000 has an average height B1 of about 4 μm, average minimum distance C1 between the nanostructures 1000 is about 0.1 μm and average pitch width A1 of about 0.2 μm. Moreover, the average width of each of the first nanostructures 1000 is about 0.05 to 0.3 μm. However, the height, density, pitch and the width of each of the first nanostructures are not limited hereby. For example, the height of the first nanostructure 1000 may be as low as 2 μm and as high as 20 μm or more depend on the dislocation density of the substrate, and the average pitch width A1 can be as low as 10 nm to 0.1 μm and as high as 0.3 μm, and the average width of each of the nanostructure can be 0.05 to 0.15 μm and 0.15 to 0.3 μm for various etching methods. Additionally, in term of aspect ratio, the aspect ratio of the first nanostructure should be around 20 to 500. However, in actual practice, the first nanostructures 1000 are suggested to have a height of at least 4 μm in order to better improve the strength performance on a IC grade silicon wafer. Moreover, although the first nanostructures 1000 having the height of 2-4 um already improves the strength thereof , however, the first nanostructures 1000 is suggested to has a height of 4-6 μm or 6-8 μm on solar grade silicon wafer for better practice.

In order to explain the suggested height of at least 4 μm, it can be discussed in two regions separated at the nanostructure height (or nano-hole depth) of 4 μm. Before forming the nanostructure onto the first surface of the substrate, the substrate (or called as the plate) may contain only flaws (or called imperfections or damages), where a flaw acts as a discontinuity introduced into the substrate in the simulation. When applying bending stress, major principal stress trajectories in the substrate cannot transmit through the discontinuity, and end up bending and concentrating around a flaw instead. The maximum stress and SCF occur around a flaw because of an abrupt change of major principal stress trajectories. When the nano-hole depth is equal to 2 μm, the flaw and the nano-structures formed thereon are encountered at the same location that causes multiple stress concentration. In general, the multiple SCF is larger than either the SCF of a flaw or the SCF of a single nano-structure. However, the parallel nano-structures form the stress-free zone based on the stress shielding effect. The stress-free zone smoothes major principal stress trajectories and decreases the maximum stress and the multiple SCF. When the nano-structure depth is larger than 4 μm on an IC grade silicon wafer, the SCF gradually increases with the increase of the nano-hole depth. However, the stress shielding effect slows down stress concentration, slowly leading to an increased SCF.

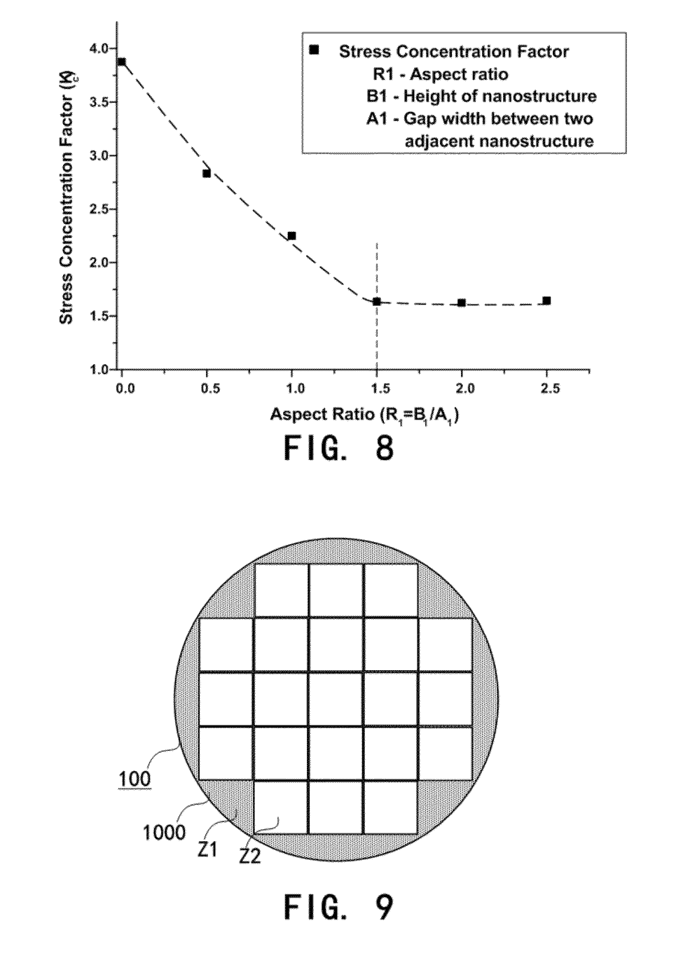

Please refer to FIG. 7A and FIG. 7B. FIG. 7A depicts a schematic diagram illustrating a nano-hole depth/bending stress chart of the first nanostructures on the substrate. In FIG. 7A, it is clearly shown that when the height of the first nanostructure (shown as nano-hole depth) is less than 4 μm, the SCF decreases rapidly, where by the said description, the criticality of the 4 μm height of the nanostructure is thereby proved. Furthermore, while the first nanostructures 1000 have an average height (depth) B1 of about 4 μm, average width C1 of about 0.1 μm and average pitch A1 of about 0.2 μm, the bending strength thereof can be improved to 1.02 GPa in comparison to the 0.17 Gpa of the substrate without the nanostructure formed on the surface thereof as shown in FIG. 8.

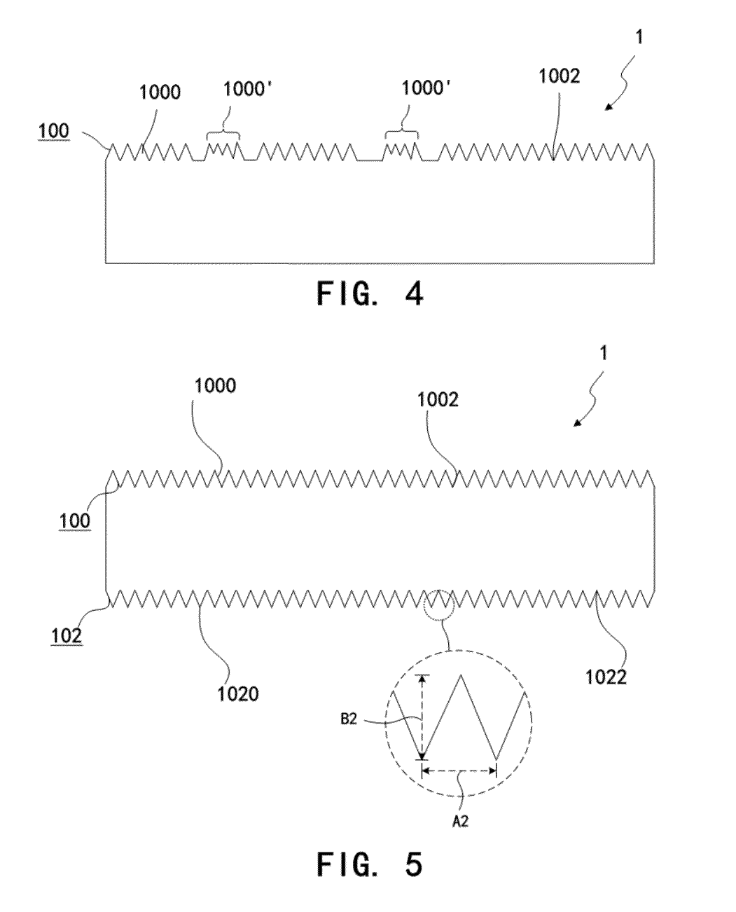

Additionally, each of the first nanostructures 1000 can be formed independently on the first surface 100 of the substrate 1, while on the other hand, multiple adjacent first nanostructures 1000 can also be formed as a group 1000′ (shown in FIG. 4). In practical application, the first nanostructures 1000 can be formed through an etching process, for example an electrochemical etching process.

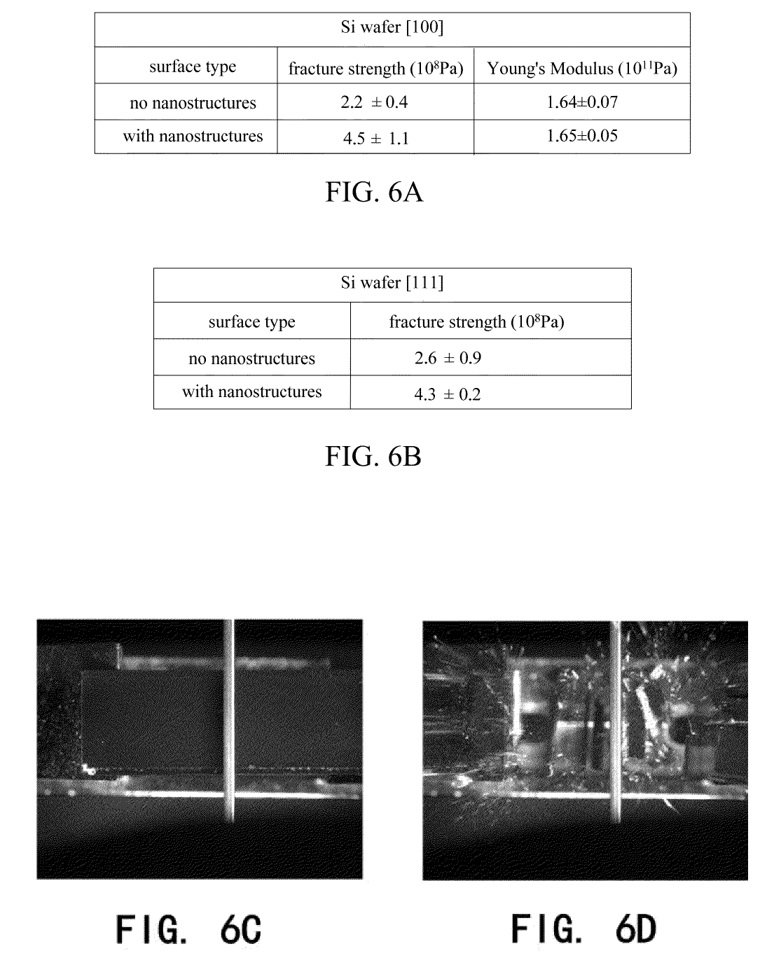

Please refer to FIG. 5. FIG. 5 is a sectional view illustrating the substrate 1 according to another embodiment of the present invention. As shown in FIG. 5, the substrate 1 further has a second surface 102 opposite to the first surface 100. Besides the first nanostructures 1000 that are formed on the first surface 100 of the substrate 1, the substrate 1 further includes a plurality of second nanostructures 1020 that protrude from the second surface 102 of the substrate 1. In this embodiment of the present invention, the substrate 1 and the second nanostructures 1020 are made of the same material, however, the second nanostructure can also be a hole or any concave shaped structure formed on the surface of the substrate in some cases.

Equivalently, the second nanostructures 1020 can be shaped as a nanotip or a nanorod. The distribution of the second nanostructures 1020 on the second surface 102 of the substrate 1 can be similar to one of the first nanostructures 1000, so it will not be repeated here. In practical application, the second nanostructures 1020 can also be formed through an etching process, for example an electrochemical etching process.

As shown in the enlarged area of FIG. 5. A second aspect ratio R2 is defined by the second nanostructures 1020. The formula of the second aspect ratio is R2=B2/A2, wherein A2 is a gap width (or called pitch) between two adjacent tops of the second nanostructures 1020, and B1 is the height of each second nanostructure 1020. In an embodiment of the present invention, the gap width between two adjacent tops of the second nanostructures 1020 can be in the range of several dozens of nanometers to several hundreds of nanometers, and the height of each second nanostructure 1020 can be in the μm scale. Moreover, the details of the second nanostructure 1020 can be identical to the first nanostructure 1000 and therefore shall be omitted herein.

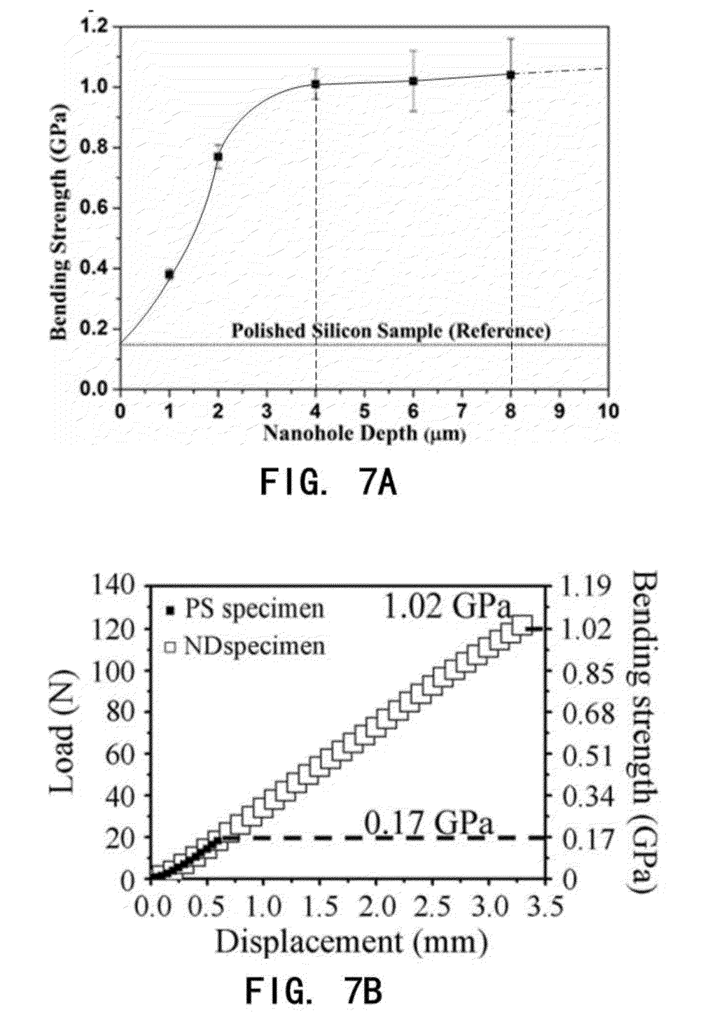

The fracture strength of the substrate according to the present invention can be measured by the three-point bending strength test. Please refer to FIG. 6C and FIG. 6D. FIG. 6C and FIG. 6D are pictures shot of the fracture strength test of the substrate according to the invention. During this fracture strength test, a monocrystalline test piece is used for demonstration. The surface of the monocrystalline test piece has a crystal orientation of [100] or [111].

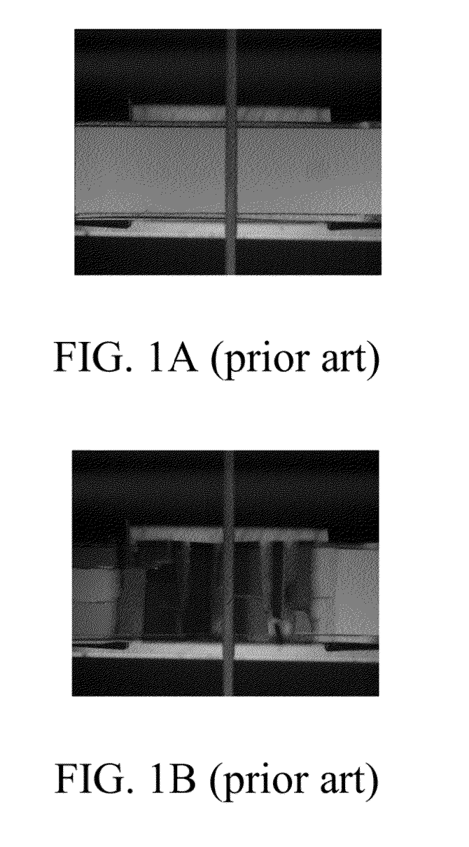

As shown in FIG. 6C to FIG. 6D, when the test piece is beyond its bearing, the test piece fracture is smashed. The smashing phenomenon shows that the test piece is fractured under ultimate energy. There is a corresponding example of the fracture difference between bullet-proof glass and normal glass, which may imply that the test piece in FIG. 6C to FIG. 6D has better fracture strength than the test piece in FIG. 1A to FIG. 1B.

Please refer to FIG. 6A and FIG. 6B. FIG. 6A and FIG. 6B are testing data from the fracture strength test of the substrate according to the invention. There are two monocrystalline test pieces respectively with a [100] crystal orientation and [111] crystal orientation to be used for demonstration It should be noted that in the fracture strength test, the cracks on the test piece usually appear on the stressed surface, and then continue to further extend. Therefore, the fracture strength test in the invention focuses on the Si wafer with nanostructures on the stressed surface.

As shown in FIG. 6A and FIG. 6B, regardless of whether the crystal orientation is [100] or [111], the measured fracture strength of the Si wafer is considerably enhanced. It can be concluded that the monocrystalline test piece of FIG. 6C to FIG. 6D has better fracture strength when compared to the monocrystalline test piece in the prior art. Besides, these two Si wafers with different crystal orientation types has substantially the same Young's Modulus. That is to say that the fracture strength of the monocrystalline test piece according to the present invention can be enhanced through surface processing without changing the material.

Please refer to FIG. 2A and FIG. 2B again. It can be seen that the first nanostructures 1000 protrude from the first surface 100 of the substrate 1. Therefore, there is a plurality of first notches 1002 formed between the first nanostructures 1000. The reason being that the fracture strength can then be considerably increased is due to the stress being evenly distributed to the first notches 1002 of the Si wafer according to the present invention, rather than being concentrated to some specific area in the traditional design of the prior art. While the loading increasing, each first notch 1002 may have a crack, which may be further extended and lead to the smashing fracture of the Si wafer. Because of the stress-distribution function of the first notches 1002, the Si wafer in the present invention can stand larger loads while having better fracture strength when compared to a traditional Si wafer. Equivalently, there can also be a plurality of second notches 1022 between the second nanostructures 1020.

In a preferred embodiment of the present invention, the nanostructures are formed on the stress-bearing surface of the substrate, such that the nanostructures are fully functional. It should be noted that the nanostructures are not limited to being located on the stress-bearing surface, but can be implemented according to the needs of the practical application. Furthermore, a method for improving the fracture strength of a substrate is also disclosed herein. More specifically, the said method comprises a major step of forming the said and the following first nanostructure and/or second nanostructure on the first/second surface of the substrate.

Furthermore, a term of dislocation density is utilized to measure the number of dislocations in a unit volume of a crystalline material. Two methods are used to measure this parameter. In the first method, the total length of dislocation line in a unit volume is measured and divided by the volume to give:

r_{D}=(L/l³)m⁻²

In the second method the number of dislocation lines crossing unit area in the sample is counted to give:

r_{D}=(n/l²)m⁻²

This second method is frequently easier to apply with the dislocations being revealed by chemical etching. A count of the number of etch pits per unit area (EPD or ea) on the etched surface gives the dislocation density.

Moreover, for example, solar grade mono-si has a dislocation density of <2000 ea/cm², IC grade Si has a dislocation density of dislocation density <50 ea/cm², IC test grade Si has a dislocation density of dislocation density <100 ea/cm², sapphire has a dislocation density of <1E3˜1E4 ea/cm², SiC has a dislocation density of micro pipe density: <1˜<50 ea/cm², while the definition of unit is defined as ea/cm² or EPD/cm² (etch pit density).

Furthermore, dislocation density is measure of the defects per unit volume, the depth of defects are equivalently affect the strength of wafer, while larger the defect density, deeper nanostructure will be required. Solar grade silicon has larger defect density. So, it required the about 8 um depth of nanostructures, meanwhile, IC grade silicon wafers have lower defect density compared to solar grade wafers. So, it required comparatively lower depth of nanostructures, around 4 um deep. In summary, larger the defect density, deeper the nanostructures is required for the improvement.

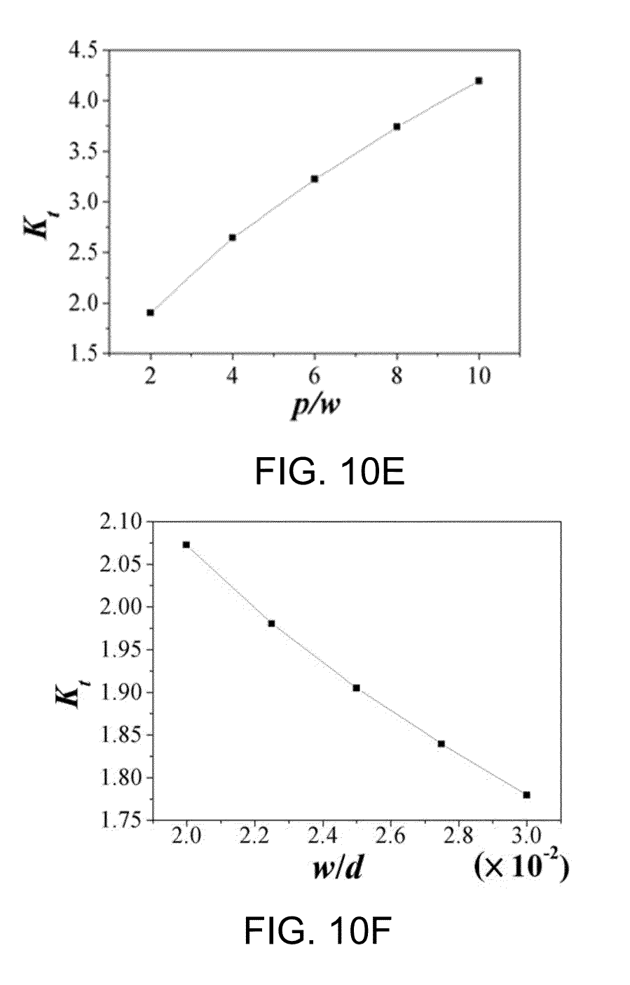

Accordingly, a simulation is done for presenting the relationship of pitch width and depth of nanostructures. Please refer to the FIG. 10A to 10F which depicts a schematic figure of relationship of pitch width and depth of nanostructures respectively. In the figures, Kc is defined as the stress concentration factor, max is defined as the maximum stress, σₙₒₘ is defined as the nominal stress. In the experiment, all the samples are applied under same force and nominal stress is taken from the flat sample (perfectly no defect) with no notch and nanostructure formed thereon. In the figures, it is clearly shown that the 4 um depth nano-hole is good to saturate the stress and the effect of reducing the stress can even be seen from 2 um depth.

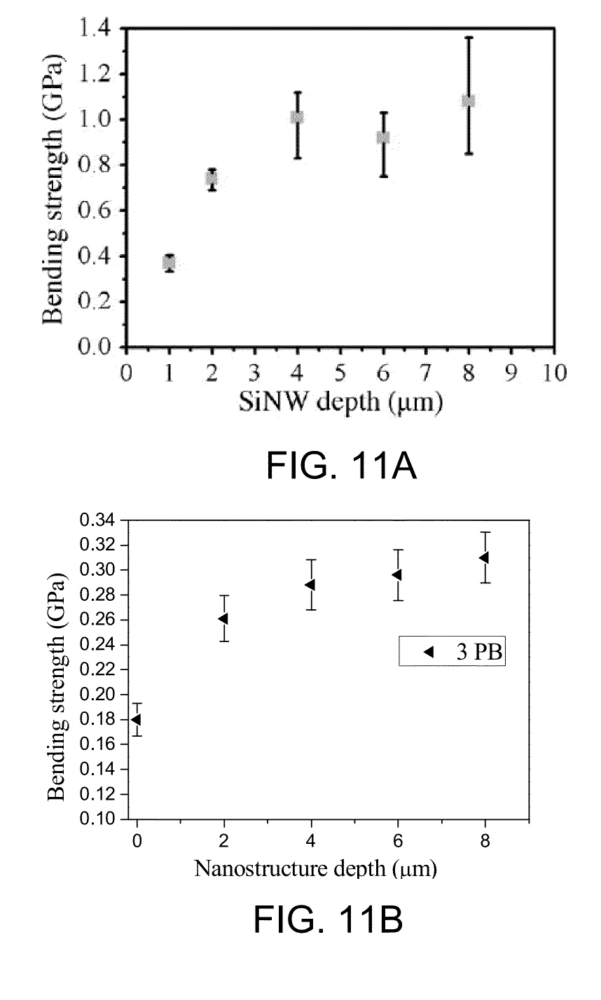

Finally, another simulation is done, please refer to the FIG. 11A and FIG. 11B which depicts a schematic figure of relationship of nanostructure depth and bending strength of the IC class wafer and solar class wafer respectively. In the FIG. 11A, it is clearly shown that the IC class wafers need only 2 to 4 um height of nanostructures for significant improvement because of the lower surface defects. Furthermore, larger depth of nanostructures (for example: around 8 um) has larger variations in strength improvement. Moreover, solar grade wafers need nanostructures having the height of 6 to 8 um since solar grade wafer has more surface defects than IC grade wafers.

Compared to prior art, the substrate of the invention has high fracture strength, such that the substrate can withstand an outside impact without breaking Accordingly, the substrate of the invention can prevent the Si wafer material from being wasted, while also elevating the yield of the process.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. A substrate with high fracture strength, comprising:
a substrate having a first surface, the first surface having a dislocation density in a range of 10 ea/cm² to 2,000 ea/cm²; and
a plurality of first nanostructures formed on the first surface of the substrate, each of the heights of the plurality of first nanostructures being in a range of 2 μm to 20 μm, each aspect ratio of the plurality of first nanostructures being in a range of 20 to 200, the first aspect ratio R1 is defined by a formula of R1=B1/D1, wherein D1 is an average width of each of the first nanostructures, and B1 is a height of each first nanostructure.

2. The substrate of claim 1, wherein the substrate is a monocrystalline substrate.

3. The substrate of claim 2, wherein the monocrystalline substrate is an IC test grade silicon substrate, each of the heights of the plurality of first nanostructures being in a range of 4 μm to 9 μm.

4. The substrate of claim 2, wherein the monocrystalline substrate is an IC grade silicon substrate, each of the heights of the plurality of first nanostructures being in a range of 2 μm to 9 μm.

5. The substrate of claim 1, wherein the first surface is a tension bearing surface of the substrate.

6. The substrate of claim 1, wherein the gap width between two adjacent tops of the first nanostructures is in the range of 0.1 μm to 0.2 μm.

7. The substrate of claim 1, wherein each of the first nanostructures having an pitch of 0.1 to 0.3 μm.

8. The substrate of claim 1, wherein the height of the first nanostructure is between 4 μm to 9 μm.

9. The substrate of claim 1, wherein the substrate has a second surface, the second surface having a dislocation density in a range of 10 ea/cm² to 2,000 ea/cm²; and a plurality of second nanostructures formed on the second surface of the substrate, each of the heights of the plurality of second nanostructures being in a range of 2 μto 20 μm, each aspect ratio of the plurality of second nanostructures being in a range of 20 to 200, the second aspect ratio R1 defined by a formula of R1=B1/D1, wherein D1 is an average width of each of the second nanostructures, and B1 is the height of each second nanostructure.

10. The substrate of claim 9, wherein the substrate is a monocrystalline substrate.

11. The substrate of claim 9, wherein the monocrystalline substrate is an IC test grade silicon substrate, each of the heights of the plurality of first nanostructures being in a range of 4 μm to 9 μm.

12. The substrate of claim 9, wherein the monocrystalline substrate is an IC grade silicon substrate, each of the heights of the plurality of first nanostructures being in a range of 2 μm to 9 μm.

13. The substrate of claim 9, wherein the first surface is a tension bearing surface of the substrate.

14. The substrate of claim 9, wherein the gap width between two adjacent tops of the first nanostructures is in the range of 0.1 μm to 0.2 μm.

15. The substrate of claim 9, wherein each of the first nanostructures having an pitch of 0.1 to 0.3 μm.

16. The substrate of claim 9, wherein the height of the first nanostructure is between 4 μm to 9 μm.

17. The substrate of claim 9, wherein each second nanostructure substantially forms a nanorod or a nanotip.

18. The substrate of claim 1, wherein a crystal orientation of the first surface of the monocrystalline silicon substrate is [100] or [111].

19. The substrate of claim 1, wherein each first nanostructure substantially forms a nanorod or a nanotip.

20. The substrate of claim 1, wherein the first surface of the substrate comprises a working zone and a reserved zone, the reserved zone comprises at least one to be diced chip formed thereon, while the to be diced chip is adapted to be packaged after a dicing process, the reversed zone having the plurality of first nanostructure formed thereon, while the nanostructure is exposed to atmosphere with no epitaxial layer covered thereon.
